(19) United States
(12) Patent Application Publication
(10) Pub. No.: US 2010/0193007 A1
(43) Pub. Date: Aug. 5, 2010

(54) Thin Film Solar Cell Module And Method For Repairing The Same

(76) Inventors: Chun-Hsiung LU, Taichung County (TW); Chien-Chung Bi, Taichung County (TW)

Correspondence Address: SINORICA, LLC, 2275 Research Blvd., Suite 500, ROCKVILLE, MD, 20850, US

(21) Appl. No.: 12/699,485

(22) Filed: Feb. 3, 2010

(30) Foreign Application Priority Data
Feb. 5, 2009 (TW) 098103628

(51) Int. Cl. H01L 31/042; H01L 31/18

(52) U.S. Cl. 136/244; 438/4; 257/E31.001

(57) ABSTRACT

This invention discloses a thin film solar cell module and method for repairing the same. The method for repairing the thin film solar cell module comprises the steps of: inspecting a plurality of unit cells so as to determine the abnormal unit cell(s) according to a loss of power generation efficiency; inspecting the abnormal unit cell(s) so as to determine a suitable separation groove; and filling-in the suitable outside separation groove so that the abnormal unit cell is electrically short connected with an adjacent unit cell of the abnormal unit cell.

### BACKGROUND OF THE INVENTION

1. Technical Field

The present invention relates to a thin film solar cell module and the method for repairing the same, and more particularly to the repairing method for eliminating short-circuits current in the thin film solar cell by electrically connected an abnormal unit cell with an adjacent unit cell so as to make the thin film solar cell to achieve a preset normal value of power generation efficiency.

2. Description of Related Art

A general model of thin film solar cell comprises at least a substrate, a front electrode layer, an absorber layer, and a back electrode layer stacked successively. In a manufacturing process of a thin film solar cell, the aforementioned layers are deposited and then divided, by laser cutting, into a plurality of unit cells that are connected in series. However, defects may occur due to imperfectly cut by laser and result in a short circuit in a thin film solar cell. The short circuit will diminish power generation efficiency of the thin film solar cell. In order to solve the aforementioned problem, the invention disclosed in the Japanese Patent Publication Document JP-H837317 is an inspecting and repairing method for defects in a thin film solar cell. The defects in a back electrode layer are inspected and located by a thermal image measurement. Afterwards the defects are removed by a pulse laser.

However, the defect is not necessary a short circuit, and the defects may not only occur in the back electrode layer but also in the front electrode layer and the absorber layer. There are still limitations to the prior arts for removing the defects or repairing thin film solar cell.

### SUMMARY OF THE INVENTION

In order to overcome the aforementioned shortcomings, the present invention provides a method for repairing a thin film solar cell and a module formed by the repairing method of the present invention. The method comprising the steps of:
(1) inspecting the plurality of unit cells so as to determine an abnormal unit cell according to a loss of power generation efficiency;
(2) inspecting the abnormal unit cell so as to locate a suitable outside separation groove; and
(3) filling-in the suitable outside separation groove by a bonding process so that the abnormal unit cell is electrically short connected with an adjacent unit cell of the abnormal unit cell.
Therefore, the primary object of the present invention is to provide a repairing method for repairing a thin film solar cell that a plurality of unit cells is inspected to determine an abnormal unit cell according to a loss of power generation efficiency. The abnormal unit cell(s) is then inspected to locate a suitable outside separation groove. The suitable outside separation groove is filled-in by a bonding process carried out by welding-bonding or bonding with a conductive material to repair the suitable outside separation groove. Therefore, the abnormal unit cell is electrically short connected with an adjacent unit cell of the abnormal unit cell to make sure the thin film solar cell to achieve the preset normal value of power generation efficiency.
Another object of the present invention is to provide a method for repairing a thin film solar cell having the defects occurred in the front electrode layer, the absorber layer, or the back electrode layer of the thin film solar cell. The defects can be inspected and repaired so as to avoid the diminish of the power generation efficiency of the thin film solar cell resulted from the defects.
Still another object of the present invention is to provide a thin film solar cell formed by the repairing method of the present invention. After repairing, the thin film solar cell can achieve the preset normal value of power generation efficiency.
Still another object of the present invention is to provide a thin film solar cell formed by the repairing method of the present invention. Either occurred in the front electrode layer, the absorber layer, or the back electrode layer of the thin film solar cell, the defects can be inspected and repaired so as to avoid the diminish of the power generation efficiency of the thin film solar cell resulted from the defects.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is a flowchart of a method for repairing a thin film solar cell according to a first preferred embodiment of the present invention.

FIG. 2 is a lateral view of an abnormal unit cell in a thin film solar cell according to a first preferred embodiment of the present invention.

FIG. 3 is a lateral view of a thin film solar cell repaired by the method of the present invention according to a first preferred embodiment of the present invention.

FIG. 4 is a lateral view of a thin film solar cell repaired by the method of the present invention according to a second preferred embodiment of the present invention.

### DETAILED DESCRIPTION OF THE PREFERRED EMBODIMENT

Some particular embodiments of the invention will be described in detail for purpose of illustration, and one of ordinary skill in the art can easily understand the advantages and efficacy of the present invention through the disclosure of the specification. It is to be understood that alternative embodiments may be possible for the implement and application of the present invention while numerous variations will be possible to the details disclosed in the specification on the strength of diverse concepts and applications without going outside the scope of the invention as disclosed in the claims.

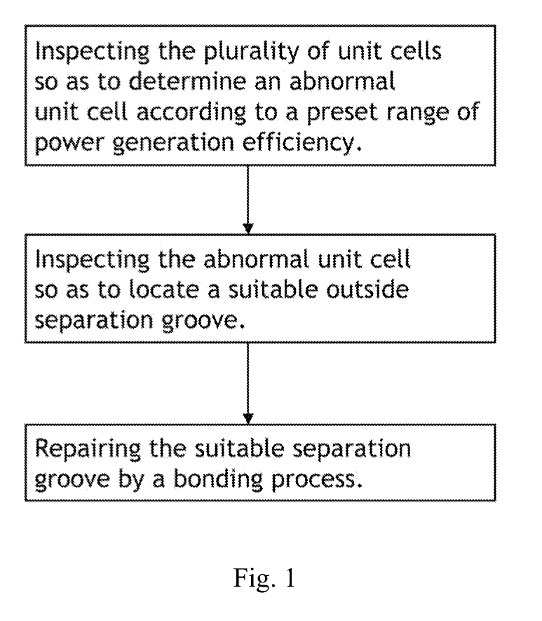

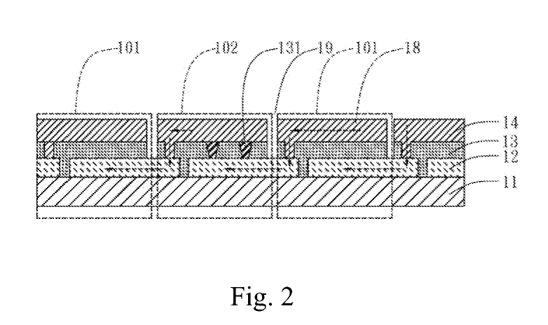

Please refer to FIG. 1, which is a flowchart of a method for repairing a thin film solar cell according to a first preferred embodiment of the present invention. As shown in FIG. 2, the thin film solar cell comprises a plurality of unit cells 101. Each unit cell 101 comprises a substrate 11, a front electrode layer 12, an absorber layer 13, and a back electrode layer 14. In addition, each unit cell 101 further comprises an outside separation groove 19. The method for repairing a thin film solar cell comprises the following steps. Step 1: The plurality of unit cells 101 is inspected to determine an abnormal unit cell 101 according to a loss of power generation efficiency. The loss of power generation efficiency is preferable at least 5%. Nevertheless, the value of the loss of power generation efficiency varies from the kind of the thin film solar cells. That is, if the power generation efficiency of the unit cell 101 is found to equal to, or be lower than, 95% of the normal power generation efficiency of a normal unit cell, that unit cell is determined as the abnormal unit cell. The inspecting of the plurality of the unit cell can be carried out by the following inspect methods: electroluminescent (EL) inspection, infrared (IR) inspection, optical microscopy (OM) or inspecting by a solar simulator. And the above-mentioned inspect method can inspect defects in different layers.

Step 2: Please refer to FIG. 2. After Step 1, at least one abnormal unit cell 102 is found and determined. The abnormal unit cell(s) 102 comprises at least one defect 131 in the front electrode layer 12, the absorber layer 13, or the back electrode layer 14. The defect in the layer, for example, is a pinhole due to an insufficient surface smoothness. The abnormal unit cell(s) 102 is then inspected to locate a suitable outside separation groove 19. The defects 131 will result in short-circuit current. The suitable outside separation groove 19 is the outside separation groove that is near to the defect 131 (referring to FIG. 2). After the repairing process, the current 18 shall go by-pass the region of the defect 131.

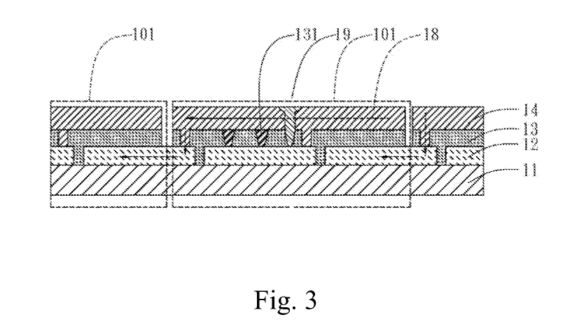

Step 3: The suitable outside separation groove 19 located in Step 2 is filled-in by a bonding process so that the abnormal unit cell 102 is electrically short connected with an adjacent unit cell 101 of the abnormal unit cell 102. Referring to FIG. 3, the bonding process is carried out after locating the suitable outside separation groove 19. The bonding process is carried out by welding-bonding, bonding with a conductive adhesive, or bonding with a conductive tape to repair the suitable outside separation groove. The welding bonding is preferred. The welding-bonding can be thermo-welding or ultrasonic welding. And the material used for welding-bonding can be zinc, chromium, nickel, an alloy of zinc, an alloy of chromium, or an alloy of nickel. The material used for the bonding with the conductive adhesive is a copper adhesive or a silver adhesive. Specifically, the bonding process is carried out by filling-in the suitable outside separation groove 19 to a depth of the back electrode layer 14. The suitable outside separation groove 19 can also further be filled-in to the depth of the absorber layer 13 (as shown in FIG. 3) or the front electrode layer 12 according to the actual situation. In fact, losing an abnormal unit cell 102 will result in the decrease of the voltage but will not effect the current. Therefore, after the suitable outside separation groove is filled-in, the abnormal unit cell 102 is electrically short connected with the adjacent unit cell 101 of the abnormal unit cell 102. The abnormal unit cell 102 and the adjacent unit cell 101 are combined as a unit cell 101 as shown in FIG. 3. Accordingly, the current 18 goes by-pass the region of the defects 131. After eliminating short-circuits current by the bonding process, the thin film solar cell can achieve the preset normal value of power generation efficiency. And the defects 131 in the front electrode layer 12, the absorber layer 13, or the back electrode layer 14 of the thin film solar cell can be inspected and repaired so as to avoid the diminish of the power generation efficiency of the thin film solar cell resulted from the defects 131.

Generally, the material used for the substrate 11 is a transparent substrate. And the front electrode layer 12 can be either unilayered or multilayered transparent conductive oxide (TCO) whose material can be tin dioxide (SnO₂), indium tin oxide (ITO), zinc oxide (ZnO), aluminum zinc oxide (AZO), gallium zinc oxide (GZO), or indium zinc oxide (IZO). The absorber layer 13 can be of either an unilayered- or multilayered-configuration. The material used for absorber layer 13 can be a crystalline silicon semiconductor, an amorphous crystalline silicon semiconductor, a semiconductive compound, an organic semiconductor, or a dye-sensitized material. A material used for the back electrode layer 14 is consisting of uni-layer or multi-layer structure of metal comprising Ag, Al, Cr, Ti, Ni or Au. The back electrode layer 14 further comprises an unilayered or multilayered transparent conductive oxide (TCO) whose material can be tin dioxide (SnO₂), indium tin oxide (ITO), zinc oxide (ZnO), aluminum zinc oxide (AZO), gallium zinc oxide (GZO), or indium zinc oxide (IZO).

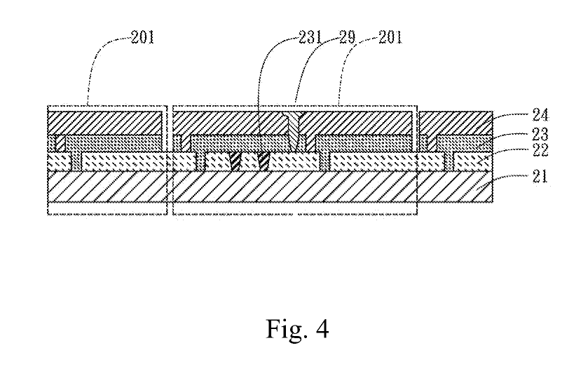

Please refer to FIG. 4, which is a perspective illustration of a thin film solar cell module according to the second preferred embodiment of the present invention. The thin film solar cell module comprises a plurality of unit cells 201 electrically connected with each other. The unit cells 201 comprise a substrate 21, a front electrode layer 22, an absorber layer 23, and a back electrode layer 24. Each unit cell 201 further comprises an outside separation groove 29. The thin film solar cell is formed by a repairing method according to the first embodiment as previously described. The filling-in of the outside separation groove 29 by a bonding process is described in the first preferred embodiment of the present invention. The repairing method of the present invention can make a thin film solar cell to achieve the preset normal value of power generation efficiency. And the defects 231 occurred in the front electrode layer 22, the absorber layer 23, or the back electrode layer 24 of the thin film solar cell can be inspected and repaired so as to avoid the diminish of the power generation efficiency of the thin film solar cell resulted from the defects 231.

Although some particular embodiments of the invention have been described in detail for purposes of illustration, it will be understood by one of ordinary skill in the art that numerous variations will be possible to the disclosed embodiments without going outside the scope of the invention as disclosed in the claims.

What is claimed is:

1. A method for repairing a thin film solar cell, the thin film solar cell comprising a plurality of unit cells, each unit cell comprising a substrate, at least a front electrode layer, a absorber layer, and a back electrode layer, wherein each unit cell further comprises an outside separation groove, the method for repairing a thin film solar cell being characterized in comprising the steps of:
inspecting the plurality of unit cells so as to determine an abnormal unit cell according to a loss of power generation efficiency;
inspecting the abnormal unit cell so as to locate a suitable outside separation groove; and
filling-in the suitable outside separation groove by a bonding process so that the abnormal unit cell is electrically short connected with an adjacent unit cell of the abnormal unit cell.

2. The method for repairing a thin film solar cell of claim 1, wherein the bonding process is carried out by a method selected from the group consisting of welding-bonding, bonding with a conductive adhesive, and bonding with a conductive tape to repair the suitable outside separation groove.

3. The method for repairing a thin film solar cell of claim 2, wherein the welding-bonding is thermo-welding or ultrasonic welding.

4. The method for repairing a thin film solar cell of claim 2, wherein a material used for welding-bonding is selected from the group consisting of zinc, chromium, and nickel, an alloy of zinc, an alloy of chromium, and an alloy of nickel.

5. The method for repairing a thin film solar cell of claim 2, wherein the conductive adhesive is a copper adhesive or a silver adhesive.

6. The method for repairing a thin film solar cell of claim 1, wherein the bonding process is carried out by filling-in the suitable outside separation groove to a depth of the back electrode layer.

7. The method for repairing a thin film solar cell of claim 6, wherein the bonding process is carried out by filling-in the suitable outside separation groove further to the depth of the absorber layer.

8. The method for repairing a thin film solar cell of claim 6, wherein the bonding process is carried out by filling-in the suitable outside separation groove further to the depth of the front electrode layer.

9. The method for repairing a thin film solar cell of claim 1, wherein the step of inspecting the plurality of unit cells is executed by an inspect method to determine power generation efficiency.

10. The method for repairing a thin film solar cell of claim 9, wherein the inspect method is selected from the group consisting of electroluminescent (EL) inspection, infrared (IR) inspection, optical microscopy (OM) and inspecting by a solar simulator.

11. The method for repairing a thin film solar cell of claim 1, wherein the loss of power generation efficiency is greater than or equals to 5%.

12. The method for repairing a thin film solar cell of claim 1, wherein the abnormal unit cell comprises at least one defect in the front electrode layer.

13. The method for repairing a thin film solar cell of claim 1, wherein the abnormal unit cell comprises at least one defect in the absorber layer.

14. The method for repairing a thin film solar cell of claim 1, wherein the abnormal unit cell comprises at least one defect in the back electrode layer.

15. The method for repairing a thin film solar cell of claim 12 wherein the suitable outside separation groove is the outside separation groove that is near to the defect and after filling-in of the suitable outside separation groove, a current goes by-pass the region of the defects.

16. The method for repairing a thin film solar cell of claim 13, wherein the suitable outside separation groove is the outside separation groove that is near to the defect and after filling-in of the suitable outside separation groove, a current goes by-pass the region of the defects.

17. The method for repairing a thin film solar cell of claim 14, wherein the suitable outside separation groove is the outside separation groove that is near to the defect and after filling-in of the suitable outside separation groove, a current goes by-pass the region of the defects.

18. A module of thin film solar cell comprising a plurality of unit cells connected electrically, each unit cell comprising a substrate, a front electrode layer, a absorber layer, and a back electrode layer, wherein the thin film solar cell is characterized in being formed by a repairing method of claim 1.
